(19) United States
(12) Patent Application Publication
(10) Pub. No.: US 2026/0282553 A1
(43) Pub. Date: Sep. 17, 2026

(54) CHANNEL-ALL-AROUND STRUCTURE-APPLIED THREE-DIMENSIONAL MONOLITHIC COMPLEMENTARY TRANSISTOR

(71) Applicants: INDUSTRY-UNIVERSITY COOPERATION FOUNDATION HANYANG UNIVERSITY ERICA CAMPUS, Ansan-si (KR); RESEARCH & BUSINESS FOUNDATION SUNGKYUNKWAN UNIVERSITY, Suwon-si (KR)

(72) Inventors: Tae Joo PARK, Ansan-si (KR); Hyoung Sub KIM, Suwon-si (KR); Ji Hyeon CHOI, Ansan-si (KR); Yu Cheol SHIN, Ansan-si (KR)

(21) Appl. No.: 19/675,358

(22) Filed: May 12, 2026

Related U.S. Application Data
(63) Continuation of application No. PCT/KR2025/003816, filed on Mar. 25, 2025.

(30) Foreign Application Priority Data
Mar. 29, 2024 (KR) 10-2024-0042915
Mar. 5, 2025 (KR) 10-2025-0028292

(51) Int. Cl. H10D 88/00; H10D 30/00; H10D 30/01; H10D 30/67; H10D 86/01; H10D 86/40; H10D 62/10

(52) U.S. Cl. CPC H10D 88/00; H10D 30/0191; H10D 30/502; H10D 30/6757; H10D 86/0221; H10D 86/423; H10D 86/471; H10D 88/01; H10D 30/6743; H10D 30/6755; H10D 62/121

(57) ABSTRACT

A three-dimensional monolithic complementary transistor includes: a gate electrode extending in a normal direction to an upper surface of a substrate; a first type first channel layer disposed below the gate electrode; a second type second channel layer surrounding an upper surface and one region of side surfaces of the gate electrode; a drain electrode disposed on the substrate to come into contact with the first channel layer and the second channel layer; a first source electrode disposed on the substrate to come into contact only with the first channel layer between the first channel layer and the second channel layer; and a second source electrode disposed on the second channel layer to come into contact only with the second channel layer between the first channel layer and the second channel layer.

### CROSS-REFERENCE TO RELATED APPLICATION

This application is a bypass continuation of pending PCT International Application No. PCT/KR2025/003816, which was filed on March 25, 2025, and which claims priority to and the benefit of Korean Patent Application No. 10-2024-0042915 filed with the Korean Intellectual Property Office on March 29, 2024, and Korean Patent Application No. 10-2025-0028292 filed with the Korean Intellectual Property Office on March 05, 2025, the disclosures of which are incorporated herein by reference in their entirety.

### STATEMENT REGARDING FEDERALLY SPONSORED RESEARCH OR DEVELOPMENT

This invention was made with government support under “Development of CVD-based dielectric thin film process technology” of Gyeonggi-do Regional Research Center (GRRC) Project awarded by Gyeonggi Province of the Republic of Korea. The government has certain rights in the invention.

### 【Technical Field】

The present invention relates to a three-dimensional monolithic complementary transistor, and more particularly, to a channel-all-around structure-applied three-dimensional monolithic complementary transistor.

In addition, the present invention has been derived through the support of the following research project.

[Title of Subject Research] [Application 1 - Gyeonggi Province] Development of CVD-based dielectric thin film process technology

[Identification Number of Subject Research] S-2023-1650-005

[Name of Ministry] Gyeonggi Provincial Government

[Host Organization] Gyeonggi Province

[Contribution Rate] 50%

[Title of Research Project] Gyeonggi-do Regional Research Center (GRRC) Project

[Research Management Specialist Organization] Gyeonggi-do Regional Research Center (GRRC)

[Research Period] July 1, 2023 - June 30, 2024

### 【Background Art】

For decades, the semiconductor industry has been countlessly developed using the development of transistor hardware as main driving force. In particular, the recent development of various information technology (IT) industries, such as Internet of Things (IoT), communications and multimedia, is largely driven by the development of transistor technology in charge of computation. The transistor technology has achieved rapid performance improvements through continuous miniaturization (scaling), and FinFET evolved from a planar transistor is currently used as the main technology. Recently, Samsung, Intel, and TSMC tend to develop and experiment with innovative processes based on gate-all-around (GAA) to implement finer transistors. Standard cells including one or more transistors refer to logic circuits playing an essential role in the design of digital semiconductor chips, and a CMOS circuit, which is the most basic thereamong, is composed of NMOS and PMOS. Since a significant portion of the chip area is composed of these standard cells, the efficient chip area utilization is directly related to the standard cell size. Recently, the CFET technology, which vertically arranges a current planar PMOS+NMOS structure to reduce a footprint of a standard cell by half, has been proposed as one of the future innovative hardware technologies in order to implement the finer structure.

### 【Disclosure】

### 【Technical Problem】

One technical problem to be solved by the present invention is to provide a channel-all-around structure-applied three-dimensional monolithic complementary transistor.

Another technical problem to be solved by the present invention is to provide a three-dimensional monolithic complementary transistor easily integrated into a three-dimensional structure.

Still another technical problem to be solved by the present invention is to provide a three-dimensional monolithic complementary transistor capable of forming a channel through a low-temperature process.

Still another technical problem to be solved by the present invention is to provide a three-dimensional monolithic complementary transistor capable of reducing parasitic capacitance.

Still another technical problem to be solved by the present invention is to provide a three-dimensional monolithic complementary transistor capable of maintaining high gate controllability for a channel to minimize, upon device miniaturization (for example, reduction of channel length) afterward, problems such as short channel effect having occurred in transistors having general planar structures.

The technical problems to be solved by the present invention are not limited to the above description.

### 【Technical Solution】

In order to solve the above-mentioned technical problems, the present invention provides a three-dimensional monolithic complementary transistor.

According to one embodiment, the three-dimensional monolithic complementary transistor includes: a gate electrode extending in a normal direction to an upper surface of a substrate; a first type first channel layer disposed below the gate electrode; a second type second channel layer surrounding an upper surface and one region of side surfaces of the gate electrode; a drain electrode disposed on the substrate to come into contact with the first channel layer and the second channel layer; a first source electrode disposed on the substrate to come into contact only with the first channel layer between the first channel layer and the second channel layer; and a second source electrode disposed on the second channel layer to come into contact only with the second channel layer between the first channel layer and the second channel layer.

According to one embodiment, the second source electrode and the drain electrode may be prevented from overlapping with each other in the extending direction of the gate electrode.

According to one embodiment, the first source electrode and the drain electrode may overlap with each other in the extending direction of the gate electrode.

According to one embodiment, the first type may include a P type, and the second type may include an N type.

According to one embodiment, the first channel layer may include silicon (Si).

According to one embodiment, the second channel layer may include any one of an oxide semiconductor and a two-dimensional material.

According to one embodiment, the gate electrode, the first channel layer, the drain electrode, and the first source electrode may be defined as a first transistor, and the gate electrode, the second channel layer, the drain electrode, and the second source electrode may be defined as a second transistor.

According to another embodiment, the three-dimensional monolithic complementary transistor includes: a gate electrode extending in a normal direction to an upper surface of a substrate; a plurality of first type first channel layers disposed to be spaced apart from each other along the extending direction of the gate electrode; a second type second channel layer surrounding an upper surface and one region of side surfaces of the gate electrode; a drain electrode disposed on the substrate to come into contact with the first channel layers and the second channel layer; a first source electrode disposed on the substrate to come into contact only with the first channel layer between the first channel layer and the second channel layer; and a second source electrode disposed on the second channel layer to come into contact only with the second channel layer between the first channel layer and the second channel layer.

According to another embodiment, the gate electrode may be surrounded by the first channel layers.

According to another embodiment, the drain electrode may come into contact with one end of each of the first channel layers.

According to another embodiment, the first source electrode may come into contact with an opposite end of each of the first channel layers.

According to another embodiment, the second source electrode and the drain electrode may be prevented from overlapping with each other in the extending direction of the gate electrode.

According to another embodiment, the first source electrode and the drain electrode may overlap with each other in the extending direction of the gate electrode.

According to another embodiment, the first type may include a P type, and the second type may include an N type.

According to another embodiment, the first channel layer may include silicon (Si), and the second channel layer may include any one of an oxide semiconductor and a two-dimensional material.

### 【Advantageous Effects】

The three-dimensional monolithic complementary transistor according to the embodiment of the present invention is configured such that an N-type transistor having a channel-all-around (CAA) structure is stacked on top of a P-type transistor having a planar structure or a gate-all-around (GAA) structure, in which silicon may be used as a channel of the P-type transistor, and any one of an oxide semiconductor and a two-dimensional material may be used as a channel of the N-type transistor.

The channel formation may be achieved through the atomic layer deposition (ALD) process, so that the integration into the three-dimensional structure can be easily implemented. In addition, the channel formation may be achieved through a low-temperature process, so that deterioration of the lower stack due to high temperature heat treatment can be prevented. In addition, high gate controllability for a channel is maintained, so that problems such as short channel effect having occurred in transistors having general planar structures can be minimized upon device miniaturization (for example, reduction of channel length) afterward.

### 【Description of Drawings】

FIG. 1 is a view for explaining a three-dimensional monolithic complementary transistor according to a first embodiment of the present invention.

FIG. 2 is an enlarged view of part A in FIG. 1.

FIG. 3 is a view for explaining step S101 of a method for manufacturing a three-dimensional monolithic complementary transistor according to a first embodiment of the present invention.

FIG. 4 is a view for explaining step S102 of the method for manufacturing the three-dimensional monolithic complementary transistor according to the first embodiment of the present invention.

FIG. 5 is a view for explaining step S103 of the method for manufacturing the three-dimensional monolithic complementary transistor according to the first embodiment of the present invention.

FIG. 6 is a view for explaining step S104 of the method for manufacturing the three-dimensional monolithic complementary transistor according to the first embodiment of the present invention.

FIG. 7 is a view for explaining step S105 of the method for manufacturing the three-dimensional monolithic complementary transistor according to the first embodiment of the present invention.

FIG. 8 is a view for explaining step S106 of the method for manufacturing the three-dimensional monolithic complementary transistor according to the first embodiment of the present invention.

FIG. 9 is a view for explaining step S107 of the method for manufacturing the three-dimensional monolithic complementary transistor according to the first embodiment of the present invention.

FIG. 10 is a view for explaining step S108 of the method for manufacturing the three-dimensional monolithic complementary transistor according to the first embodiment of the present invention.

FIG. 11 is a view for explaining step S109 of the method for manufacturing the three-dimensional monolithic complementary transistor according to the first embodiment of the present invention.

FIG. 12 is a view for explaining step S110 of the method for manufacturing the three-dimensional monolithic complementary transistor according to the first embodiment of the present invention.

FIG. 13 is a view for explaining step S111 of the method for manufacturing the three-dimensional monolithic complementary transistor according to the first embodiment of the present invention.

FIG. 14 is a view for explaining step S112 of the method for manufacturing the three-dimensional monolithic complementary transistor according to the first embodiment of the present invention.

FIGS. 15 and 16 are views for explaining step S113 of the method for manufacturing the three-dimensional monolithic complementary transistor according to the first embodiment of the present invention.

FIG. 17 is a view for explaining step S114 of the method for manufacturing the three-dimensional monolithic complementary transistor according to the first embodiment of the present invention.

FIG. 18 is a view for explaining step S115 of the method for manufacturing the three-dimensional monolithic complementary transistor according to the first embodiment of the present invention.

FIG. 19 is a view for explaining step S116 of the method for manufacturing the three-dimensional monolithic complementary transistor according to the first embodiment of the present invention.

FIG. 20 is a view for explaining a three-dimensional monolithic complementary transistor according to a second embodiment of the present invention.

FIG. 21 is a view for explaining step S201 of the method for manufacturing the three-dimensional monolithic complementary transistor according to the second embodiment of the present invention.

FIG. 22 is a view for explaining step S202 of the method for manufacturing the three-dimensional monolithic complementary transistor according to the second embodiment of the present invention.

FIG. 23 is a view for explaining step S203 of the method for manufacturing the three-dimensional monolithic complementary transistor according to the second embodiment of the present invention.

FIG. 24 is a view for explaining step S204 of the method for manufacturing the three-dimensional monolithic complementary transistor according to the second embodiment of the present invention.

FIG. 25 is a view for explaining step S205 of the method for manufacturing the three-dimensional monolithic complementary transistor according to the second embodiment of the present invention.

FIG. 26 is a view for explaining step S206 of the method for manufacturing the three-dimensional monolithic complementary transistor according to the second embodiment of the present invention.

FIG. 27 is a view for explaining step S207 of the method for manufacturing the three-dimensional monolithic complementary transistor according to the second embodiment of the present invention.

FIG. 28 is a view for explaining step S208 of the method for manufacturing the three-dimensional monolithic complementary transistor according to the second embodiment of the present invention.

FIG. 29 is a view for explaining step S209 of the method for manufacturing the three-dimensional monolithic complementary transistor according to the second embodiment of the present invention.

FIG. 30 is a view for explaining step S210 of the method for manufacturing the three-dimensional monolithic complementary transistor according to the second embodiment of the present invention.

FIG. 31 is a view for explaining step S211 of the method for manufacturing the three-dimensional monolithic complementary transistor according to the second embodiment of the present invention.

FIG. 32 is a view for explaining step S212 of the method for manufacturing the three-dimensional monolithic complementary transistor according to the second embodiment of the present invention.

FIG. 33 is a view for explaining step S213 of the method for manufacturing the three-dimensional monolithic complementary transistor according to the second embodiment of the present invention.

FIG. 34 is a view for explaining step S214 of the method for manufacturing the three-dimensional monolithic complementary transistor according to the second embodiment of the present invention.

FIG. 35 is a view for explaining step S215 of the method for manufacturing the three-dimensional monolithic complementary transistor according to the second embodiment of the present invention.

FIG. 36 is a view for explaining step S216 of the method for manufacturing the three-dimensional monolithic complementary transistor according to the second embodiment of the present invention.

FIG. 37 is a view for explaining step S217 of the method for manufacturing the three-dimensional monolithic complementary transistor according to the second embodiment of the present invention.

FIG. 38 is a view for explaining step S218 of the method for manufacturing the three-dimensional monolithic complementary transistor according to the second embodiment of the present invention.

### Best Mode

### 【Mode for Invention】

Hereinafter, exemplary embodiments of the present invention will be described in detail with reference to the accompanying drawings. However, the technical idea of the present invention is not limited to the exemplary embodiments described herein and may be embodied in other forms. Further, the embodiments are provided to enable contents disclosed herein to be thorough and complete and provided to enable those skilled in the art to fully understand the idea of the present invention.

In the specification, when one component is mentioned as being on another component, it signifies that the one component may be placed directly on another component or a third component may be interposed therebetween. In addition, in drawings, thicknesses of films and regions may be exaggerated to effectively describe the technology of the present invention.

In addition, although terms such as first, second and third are used herein to describe various components in various embodiments of the present specification, the components will not be limited by the terms. The above terms are used merely to distinguish one component from another component. Accordingly, a first component referred to in one embodiment may be referred to as a second component in another embodiment. Each embodiment described and illustrated herein may also include a complementary embodiment. In addition, the term "and/or" is used herein to include at least one of the components listed before and after the term.

The singular expression herein includes a plural expression unless the context clearly specifies otherwise. In addition, it will be understood that the term such as "include" or "have" herein is intended to designate the presence of feature, number, step, component, or a combination thereof recited in the specification, and does not preclude the possibility of the presence or addition of one or more other features, numbers, steps, components, or combinations thereof. In addition, the term "connect" is used herein to include both indirectly connecting a plurality of components and directly connecting the components.

In addition, in the following description of the embodiments of the present invention, the detailed description of known functions and configurations incorporated herein will be omitted when it possibly makes the subject matter of the present invention unclear unnecessarily.

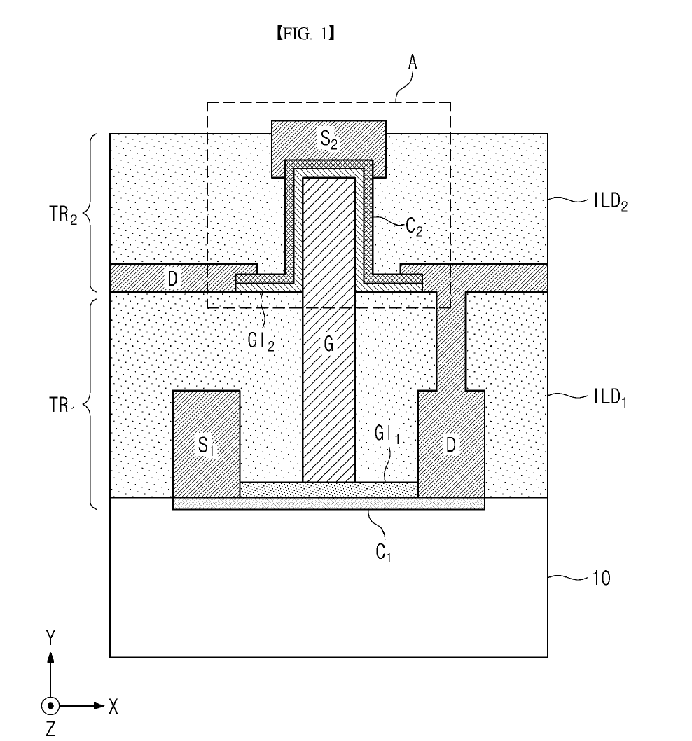

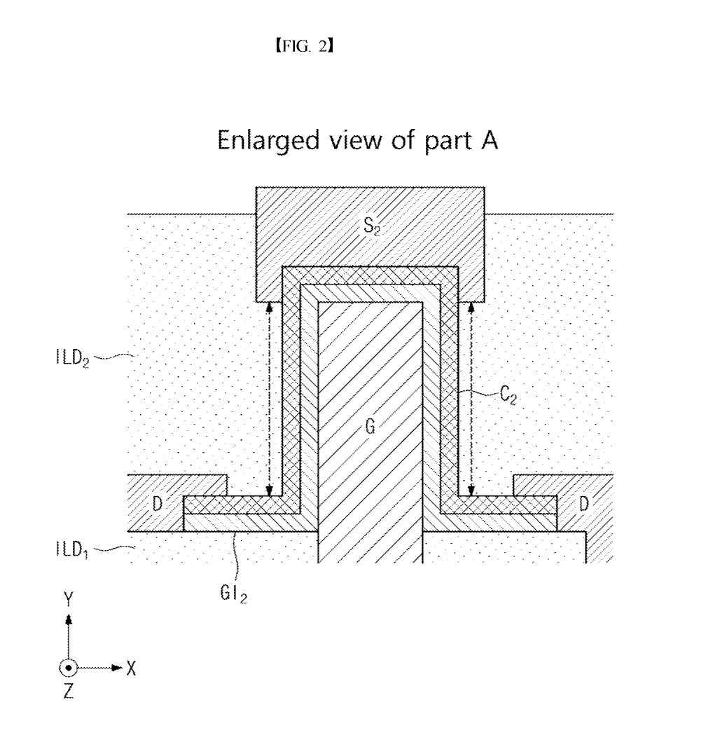

FIG. 1 is a view for explaining a three-dimensional monolithic complementary transistor according to a first embodiment of the present invention; and FIG. 2 is an enlarged view of part A in FIG. 1.

Referring to FIG. 1, the three-dimensional monolithic complementary transistor according to the first embodiment may include a substrate 10, a gate electrode G, a first channel layer C1, a second channel layer C2, a first gate insulating layer GI1, a second gate insulating layer GI2, a first source electrode S1, a second source electrode S2, a drain electrode D, a first interlayer insulating layer ILD1, and a second interlayer insulating layer ILD2. Hereinafter, each component will be described.

The substrate 10 configured to support the components of the three-dimensional monolithic complementary transistor according to the first embodiment. According to one embodiment, the substrate may be a silicon semiconductor substrate. In contrast, according to another embodiment, the substrate 10 may be any one of a compound semiconductor substrate, a glass substrate, or a plastic substrate. The type of the substrate S is not limited.

The first channel layer C1 may be disposed on the substrate 10 or formed within one region of the substrate 10. According to one embodiment, the first channel layer C1 may have a first type. For example, the first channel layer C1 may have a P type. According to one embodiment, the first channel layer C1 may include P-type silicon.

The first gate insulating layer GI1 may be disposed on the first channel layer C1. The first gate insulating layer GI1 is configured for electrical insulation between the first channel layer C1 and the gate electrode G described below, and according to one embodiment, may include silicon oxide (SiO₂). In contrast, according to another embodiment, the first gate insulating layer GI1 may include any one of hafnium oxide (HfO₂), aluminum oxide (Al₂O₃), and zirconium oxide (ZrO₂).

The gate electrode G may be disposed on the first gate insulating layer GI1 and may extend in a normal direction of an upper surface of the substrate 10 (for example, the Y-axis direction of FIG. 1). In other words, the gate electrode G may have a shape extending in a vertical direction of the substrate 10. According to one embodiment, the gate electrode G may include a metal. In contrast, according to another embodiment, the gate electrode G may include polycrystalline silicon (poly-Si). The type of material usable as the gate electrode G is not limited. According to one embodiment, the gate electrode G may be used as Vin of the complementary transistor according to the embodiment.

The first source electrode S1 may be disposed on the first channel layer C1 so as to be disposed to come into contact with one side of the first gate insulating layer GI1. According to one embodiment, the first source electrode S1 may also extend in the normal direction of the upper surface of the substrate 10 (for example, the Y-axis direction of FIG. 1) so as to have an extending length shorter than the gate electrode G. According to one embodiment, the first source electrode S1 may be used as VDD of the complementary transistor according to the embodiment.

The drain electrode D may be disposed on the first channel layer C1, in which a lower region of the drain electrode D may come into contact with an opposite side of the first gate insulating layer GI1, and an upper region of the drain electrode D may surround the second channel layer C2 and the second gate insulating layer GI2 described later.

In other words, the first source electrode S1 may be disposed to come into contact only with the first channel layer C1 between the first channel layer C1 and the second channel layer C2 described below, however, the drain electrode D may be disposed to come into contact with both of the first channel layer C1 and the second channel layer C2 described below. In addition, one region of the drain electrode D surrounding the second channel layer C2 and the second gate insulating layer GI2 described later may overlap with the first source electrode S1 in the extending direction of the gate electrode (for example, the Y-axis direction of FIG. 1).

According to one embodiment, the drain electrode D may be disposed to be spaced apart from the first source electrode S1 with the gate electrode G interposed therebetween. According to one embodiment, the drain electrode D may also extend in the normal direction of the upper surface of the substrate 10 (for example, the Y-axis direction of FIG. 1) so as to have an extending length shorter than the gate electrode G and longer than the first source electrode S1. According to one embodiment, the drain electrode D may be used as Vout of the complementary transistor according to the embodiment.

The second gate insulating layer GI2 may be disposed to surround an upper surface and one region of a side surface of the gate electrode G. In other words, the second gate insulating layer GI2 may be disposed to conformally cover the upper region of the gate electrode G along a surface profile thereof. The second gate insulating layer GI2 is configured for electrical insulation between the gate electrode G and the second channel layer C2 described below, and according to one embodiment, may include silicon oxide (SiO₂). In contrast, according to another embodiment, the second gate insulating layer GI2 may include any one of hafnium oxide (HfO₂), aluminum oxide (Al₂O₃), and zirconium oxide (ZrO₂).

The second channel layer C2 may be disposed on the second gate insulating layer GI2. More particularly, the second channel layer C2 may be disposed along a surface profile of the second gate insulating layer GI2. Accordingly, the second channel layer C2 may also surround the upper surface and the predetermined region of the side surface of the gate electrode G. According to one embodiment, the second channel layer C2 may have a second type. For example, the second channel layer C2 may have an N type. According to one embodiment, the second channel layer C2 may include any one of an oxide semiconductor and a two-dimensional material that have N-type characteristics. As described above when the second channel layer C2 is composed of any one of the oxide semiconductor or the two-dimensional material, the channel formation may be achieved through the atomic layer deposition (ALD) process, so that the integration into the three-dimensional structure can be easily implemented. In addition, the channel formation may be achieved through a low-temperature process, so that deterioration of the lower stack due to high temperature heat treatment can be prevented.

The second source electrode S2 may be disposed on the second channel layer C2 to come into contact only with the second channel layer C2 between the first channel layer C1 and the second channel layer C2. In addition, as shown in FIGS. 1 and 2, the second source electrode S2 may be disposed so as not to overlap with the drain electrode D in the extending direction of the gate electrode G (for example, the Y-axis direction of FIG. 1). Accordingly, parasitic capacitance may be reduced, so that the electrical characteristics of the complementary transistor may be improved. In contrast, when the second source electrode S2 and the drain electrode D are disposed to overlap with each other, a problem may arise in which the electrical characteristics of the complementary transistor deteriorate due to an increase in parasitic capacitance. According to one embodiment, the second source electrode S2 may be used as Ground of the complementary transistor according to the embodiment.

The first interlayer insulating layer ILD1 may be disposed between the substrate 10 and the drain electrode D surrounding the upper region of the gate electrode G to electrically insulate between the gate electrode G, the first source electrode S1 and the drain electrode D. In contrast, the second interlayer insulating layer ILD2 is disposed between the second source electrode S2 and the drain electrode D surrounding the upper region of the gate electrode G to electrically insulate between the gate electrode G, the second source electrode S2 and the drain electrode D.

The gate electrode G, the first channel layer C1, the first source electrode S1, and the drain electrode D may be defined as a first transistor TR1. In contrast, the gate electrode G, the second channel layer C2, the second source electrode S2, and the drain electrode D may be defined as a second transistor TR2.

The first transistor TR1 may have a planar structure in which the gate electrode G, the first channel layer C1, the first source electrode S1, and the drain electrode D are arranged in a plane. In contrast, the second transistor TR2 may have a channel-all-around (CAA) structure in which the second channel layer C2 surrounds the gate electrode G. In addition, the second transistor TR2 may have a structure stacked on top of the first transistor TR1 along the normal direction of the upper surface of the substrate 10.

As a result, the three-dimensional monolithic complementary transistor according to the first embodiment may have a structure in which an N-type transistor having a CAA structure is stacked on top of a P-type transistor having a planar structure, and share the gate electrode G and the drain electrode D.

The three-dimensional monolithic complementary transistor according to the first embodiment of the present invention has been described. Hereinafter, a method for manufacturing the three-dimensional monolithic complementary transistor according to the first embodiment of the present invention will be described.

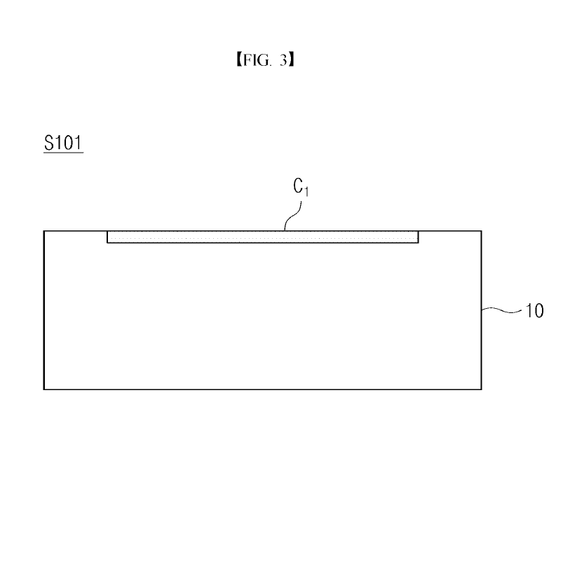

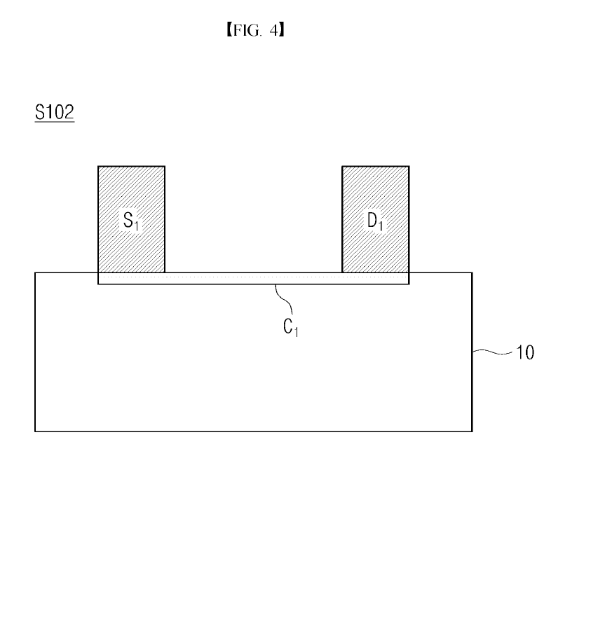

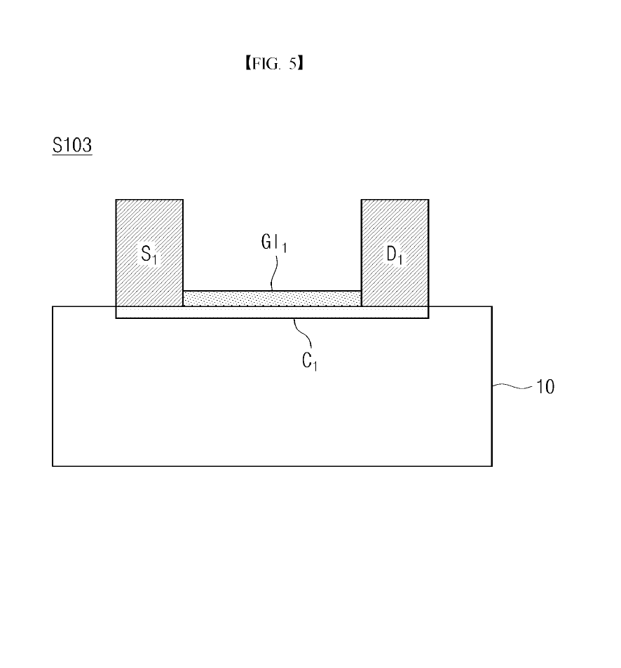

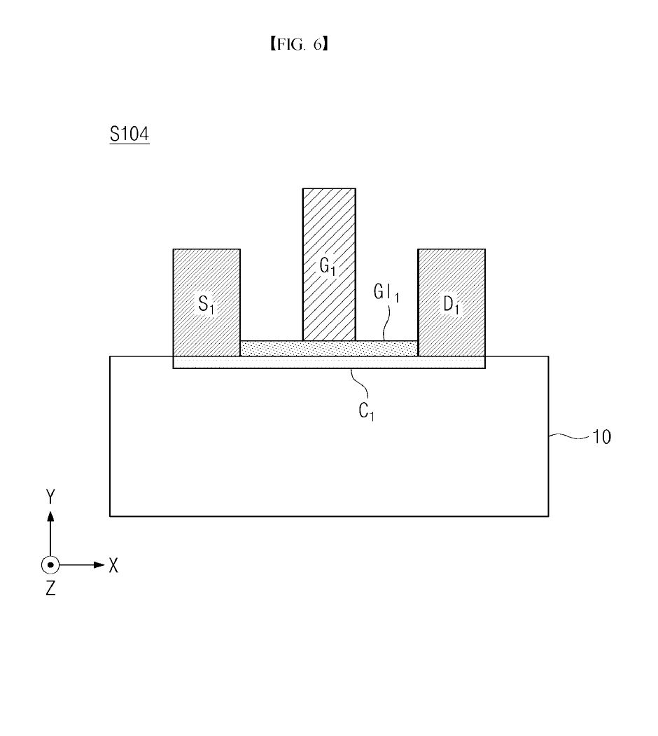

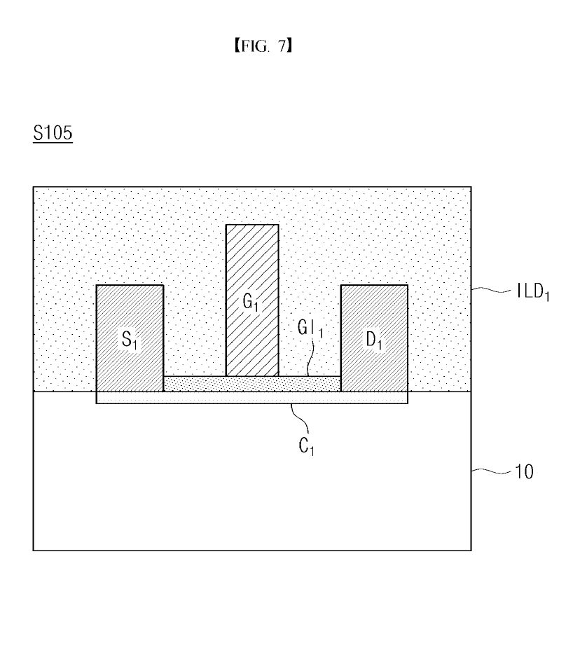

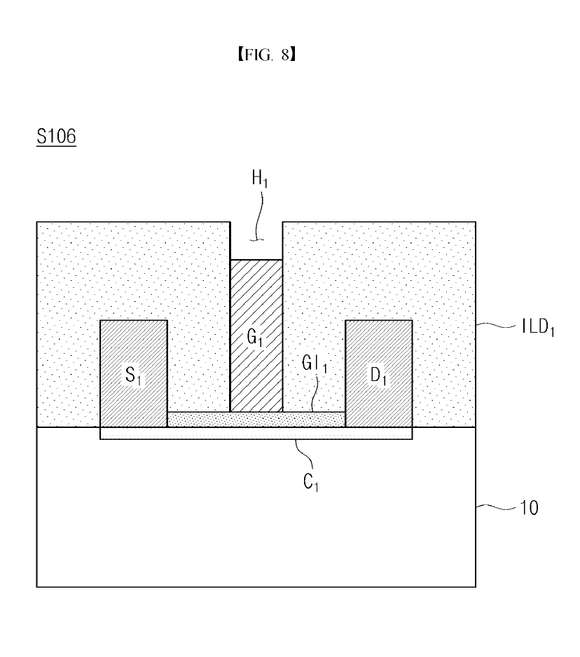

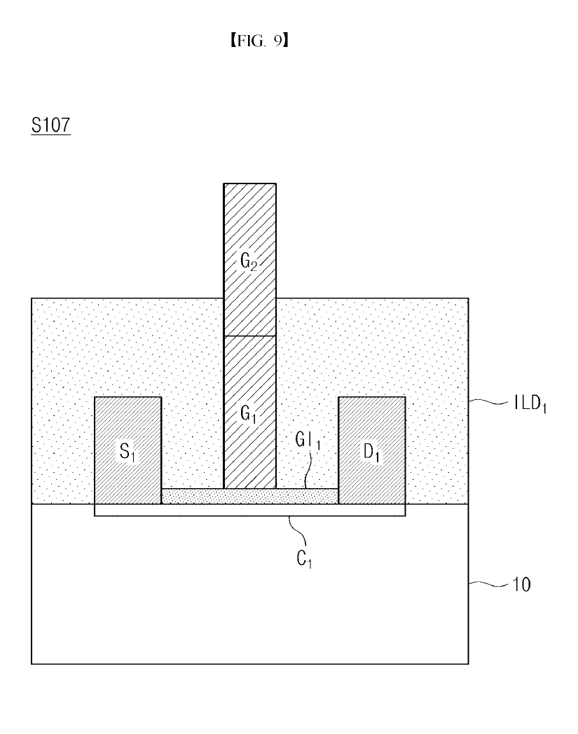

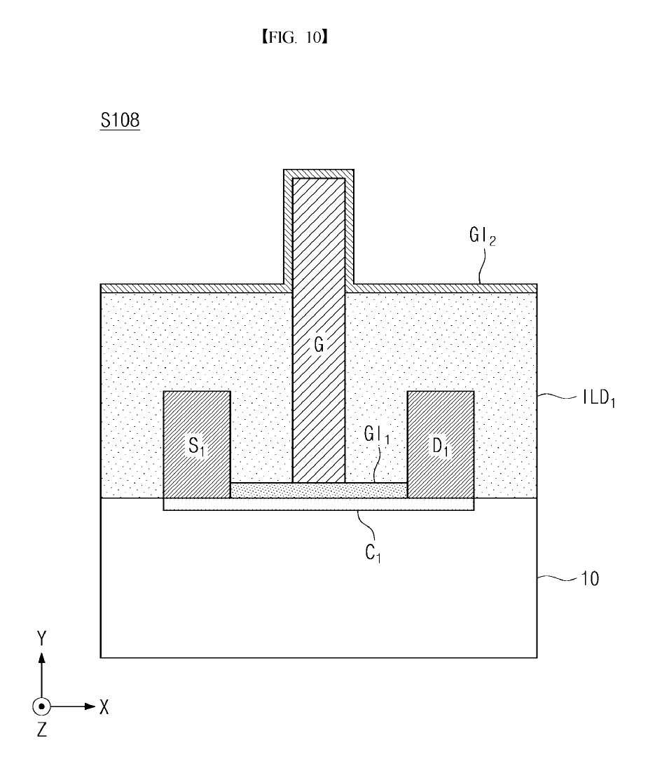

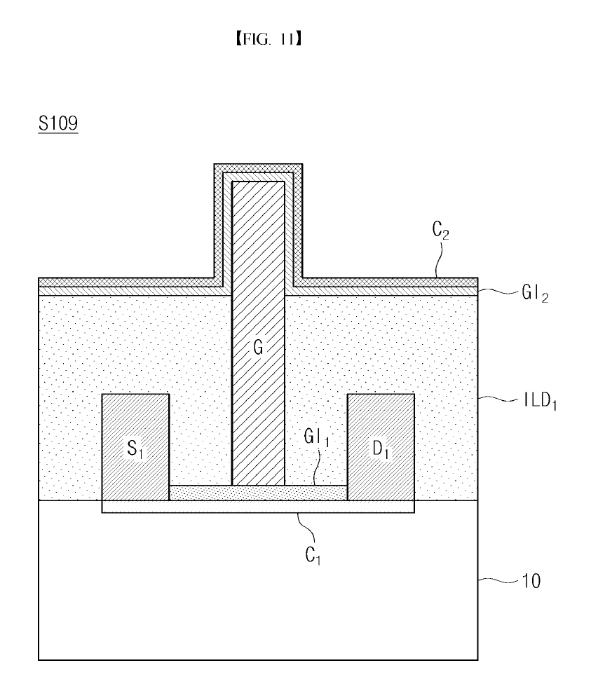

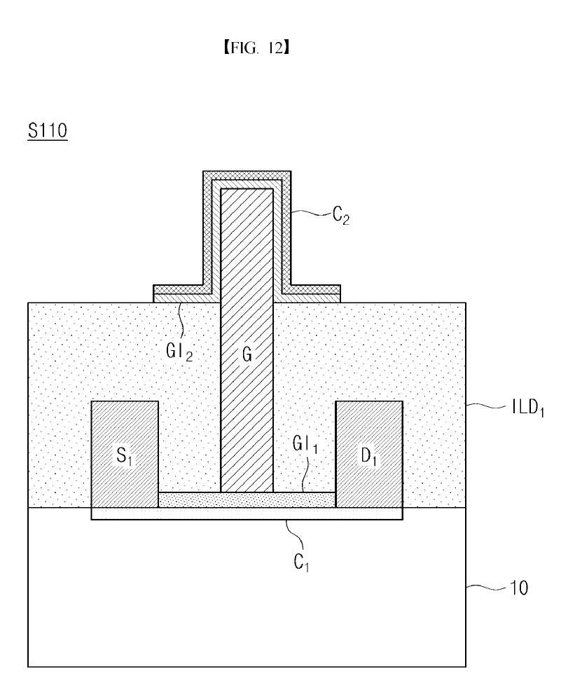

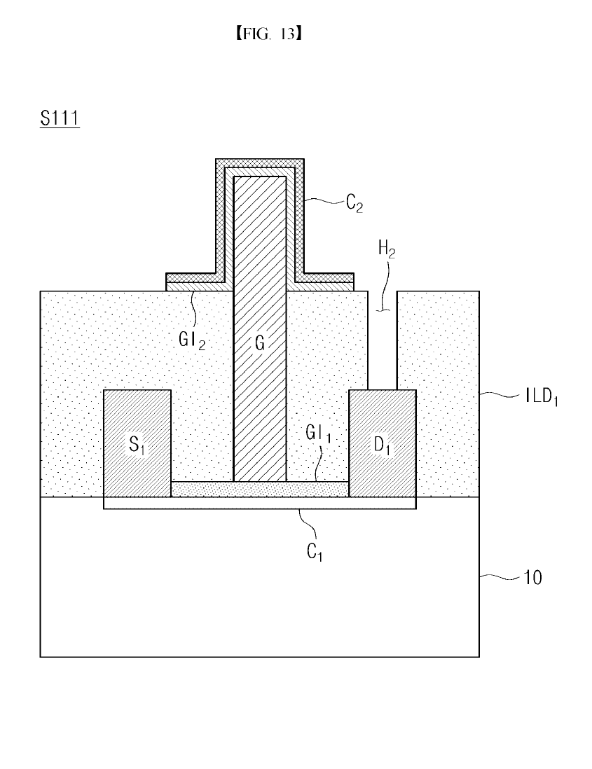

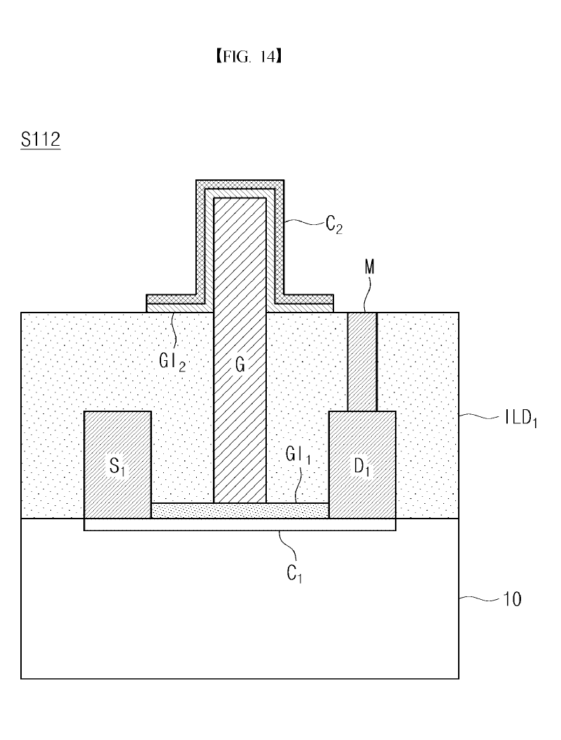

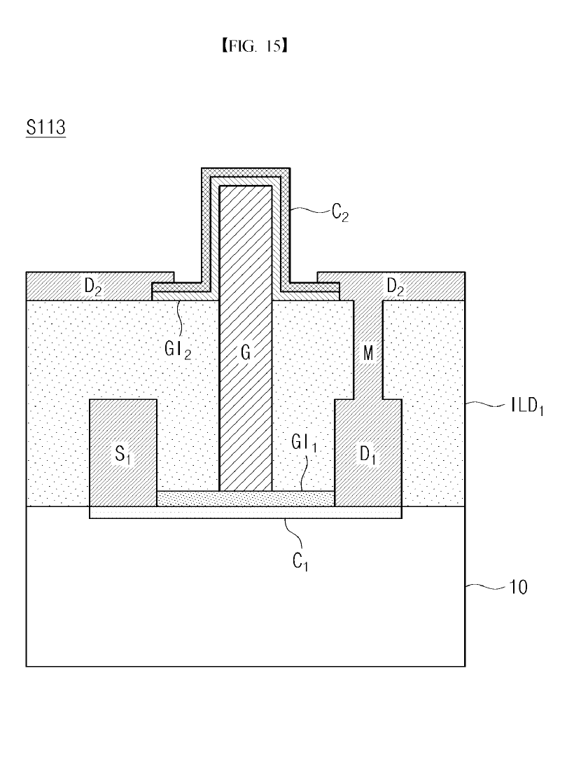

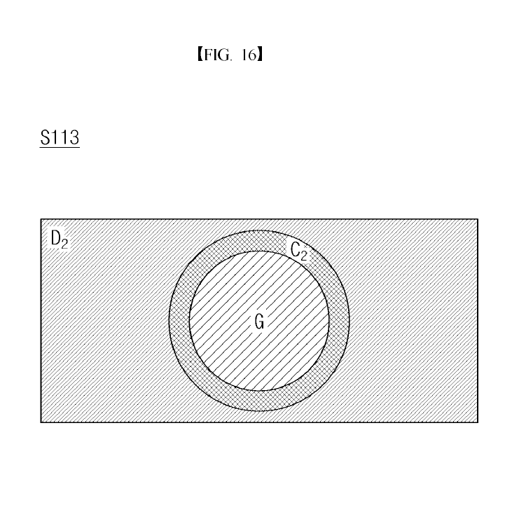

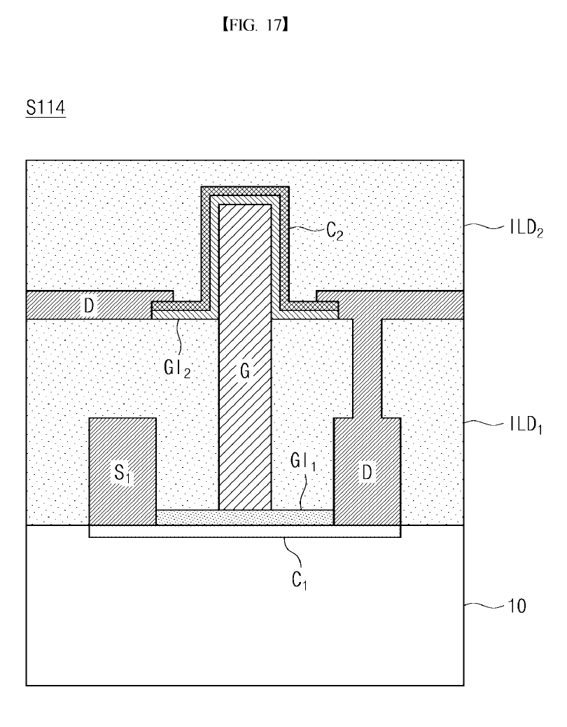

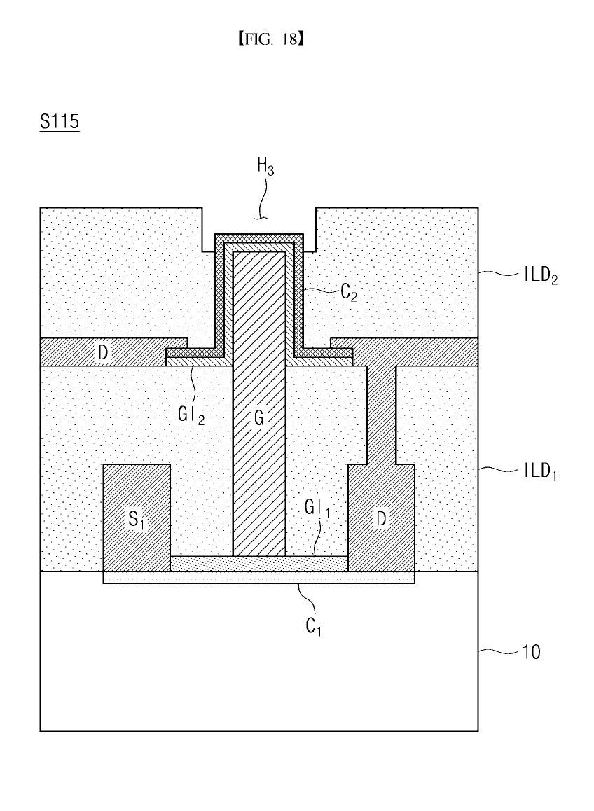

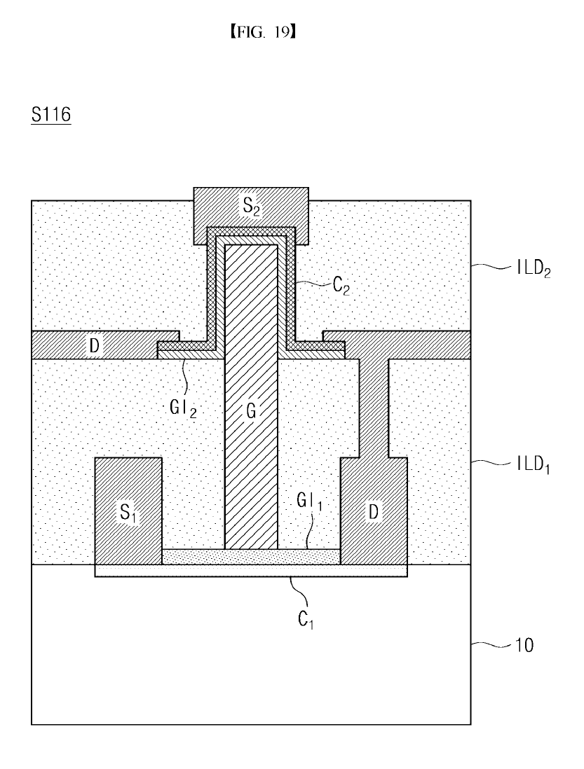

FIG. 3 is a view for explaining step S101 of a method for manufacturing the three-dimensional monolithic complementary transistor according to the first embodiment of the present invention; FIG. 4 is a view for explaining step S102 of the method for manufacturing the three-dimensional monolithic complementary transistor according to the first embodiment of the present invention; FIG. 5 is a view for explaining step S103 of the method for manufacturing the three-dimensional monolithic complementary transistor according to the first embodiment of the present invention; FIG. 6 is a view for explaining step S104 of the method for manufacturing the three-dimensional monolithic complementary transistor according to the first embodiment of the present invention; FIG. 7 is a view for explaining step S105 of the method for manufacturing the three-dimensional monolithic complementary transistor according to the first embodiment of the present invention; FIG. 8 is a view for explaining step S106 of the method for manufacturing the three-dimensional monolithic complementary transistor according to the first embodiment of the present invention; FIG. 9 is a view for explaining step S107 of the method for manufacturing the three-dimensional monolithic complementary transistor according to the first embodiment of the present invention; FIG. 10 is a view for explaining step S108 of the method for manufacturing the three-dimensional monolithic complementary transistor according to the first embodiment of the present invention; FIG. 11 is a view for explaining step S109 of the method for manufacturing the three-dimensional monolithic complementary transistor according to the first embodiment of the present invention; FIG. 12 is a view for explaining step S110 of the method for manufacturing the three-dimensional monolithic complementary transistor according to the first embodiment of the present invention; FIG. 13 is a view for explaining step S111 of the method for manufacturing the three-dimensional monolithic complementary transistor according to the first embodiment of the present invention; FIG. 14 is a view for explaining step S112 of the method for manufacturing the three-dimensional monolithic complementary transistor according to the first embodiment of the present invention; FIGS. 15 and 16 are views for explaining step S113 of the method for manufacturing the three-dimensional monolithic complementary transistor according to the first embodiment of the present invention; FIG. 17 is a view for explaining step S114 of the method for manufacturing the three-dimensional monolithic complementary transistor according to the first embodiment of the present invention; FIG. 18 is a view for explaining step S115 of the method for manufacturing the three-dimensional monolithic complementary transistor according to the first embodiment of the present invention; and FIG. 19 is a view for explaining step S116 of the method for manufacturing the three-dimensional monolithic complementary transistor according to the first embodiment of the present invention.

Referring to FIG. 3, a substrate 10 formed therein with a first channel layer C1 may be prepared (S101). According to one embodiment, the first channel layer C1 may be formed by doping one region of an upper surface of the substrate 10. For example, the substrate 10 may include silicon (Si), and the first channel layer C1 may be formed as a P type by doping the region of the upper surface of the substrate 10 by injecting an impurity therein.

Referring to FIGS. 4 and 5, a first source electrode S1 and a first drain electrode D1 may be formed on the first channel layer C1 so as to be spaced apart from each other (S102), and a first gate insulating layer GI1 may be formed on the first channel layer C1 exposed between the first source electrode S1 and the first drain electrode D1 (S103).

Referring to FIGS. 6 and 7, a first gate electrode G1 may be formed on the first gate insulating layer GI1 to extend in the normal direction of the upper surface of the substrate 10 (for example, the Y-axis direction of FIG. 6) (S104), and a first interlayer insulating layer ILD1 may be formed on the substrate 10 to cover the first source electrode S1, the first drain electrode D1, the first gate insulating layer GI1, and the first gate electrode G1 (S105).

Referring to FIGS. 8 and 9, a first hole H1 may be formed by etching one region of the first interlayer insulating layer ILD1 to expose one region of the first gate electrode G1 (S106), and a second gate electrode G2 may be formed on the exposed first gate electrode G1, that is, in the first hole H1 to extend along the extending direction of the first gate electrode G1 (S107). In addition, the second gate electrode G2 may be formed to be exposed to an outside of the first interlayer insulating layer ILD1. According to one embodiment, the first gate electrode G1 and the second gate electrode G2 may include the same material, and the first gate electrode G1 and the second gate electrode G2 may form the gate electrode G described with reference to FIGS. 1 and 2.

Referring to FIGS. 10 to 12, a second gate insulating layer GI2 may be formed to conformally cover the upper surface of the first interlayer insulating layer ILD1 and the exposed gate electrode G (S108), a second channel layer C2 may be formed on the second gate insulating layer GI2 along a surface profile of the second gate insulating layer GI2 (S109), and the second channel layer C2 and the second gate insulating layer GI2 may be etched to expose one region of the upper surface of the first interlayer insulating layer ILD1 (S110).

Referring to FIGS. 13 to 16, a second hole H2 may be formed by etching one region of the first interlayer insulating layer ILD1 to expose one region of the first drain electrode D1 (S111), the second hole H2 may be filled with a metal M (S112), and a second drain electrode D2 may be formed on the first interlayer insulating layer ILD1 to surround the second gate insulating layer GI2 and the second channel layer C2 (S113). The first drain electrode D1, the metal filled in the second hole H2, and the second drain electrode D2 may include the same material, and the first drain electrode D1, the metal filled in the second hole H2, and the second drain electrode D2 may form the drain electrode D described with reference to FIGS. 1 and 2.

Referring to FIGS. 17 to 19, a second interlayer insulating layer ILD2 may be formed on the first interlayer insulating layer ILD1 to cover the drain electrode D and the second channel layer C2 (S114), a third hole H3 may be formed by etching one region of the second interlayer insulating layer ILD2 to expose the second channel layer C2 (S115), and a second source electrode S2 may be formed on the exposed second channel layer C2, that is, in the third hole H3 (S116), in which the second source electrode S2 may be formed in the extending direction of the gate electrode G without overlapping with the drain electrode D. Accordingly, the three-dimensional monolithic complementary transistor according to the first embodiment may be manufactured.

The method for manufacturing the three-dimensional monolithic complementary transistor according to the first embodiment of the present invention has been described. Hereinafter, a three-dimensional monolithic complementary transistor according to a second embodiment of the present invention will be described.

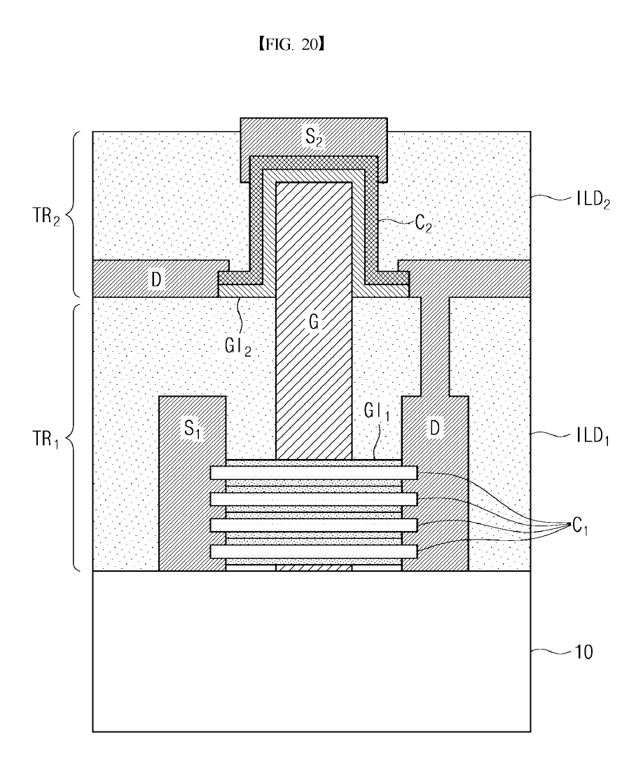

FIG. 20 is a view for explaining a three-dimensional monolithic complementary transistor according to a second embodiment of the present invention.

Referring to FIG. 20, the three-dimensional monolithic complementary transistor according to the second embodiment may include a substrate 10, a gate electrode G, a plurality of first channel layers C1, a second channel layer C2, a first gate insulating layer GI1, a second gate insulating layer GI2, a first source electrode S1, a second source electrode S2, a drain electrode D, a first interlayer insulating layer ILD1, and a second interlayer insulating layer ILD2. Hereinafter, each component will be described.

The substrate 10 configured to support the components of the three-dimensional monolithic complementary transistor according to the second embodiment, and according to the embodiment, may be a silicon semiconductor substrate. In contrast, according to another embodiment, the substrate 10 may be any one of a compound semiconductor substrate, a glass substrate, or a plastic substrate. The type of the substrate S is not limited.

The first channel layers C1 may be spaced apart from each other along the extending direction of the gate electrode G and disposed on the substrate 10 so as to be adjacent to a lower region of the gate electrode G. According to one embodiment, the first channel layer C1 may have a first type. For example, the first channel layer C1 may have a P type. According to one embodiment, the first channel layer C1 may include P-type silicon.

The first gate insulating layer GI1 may be disposed to surround the first channel layers C1. The first gate insulating layer GI1 is configured for electrical insulation between the first channel layer C1 and the gate electrode G described below, and according to one embodiment, may include silicon oxide (SiO₂). In contrast, according to another embodiment, the first gate insulating layer GI1 may include any one of hafnium oxide (HfO₂), aluminum oxide (Al₂O₃), and zirconium oxide (ZrO₂).

The gate electrode G may be disposed on the substrate 10 and may extend in the normal direction of the upper surface of the substrate 10. In other words, the gate electrode G may have a shape extending in a vertical direction of the substrate 10. In addition, the gate electrode G may surround the first channel layers C1. According to one embodiment, the gate electrode G may include a metal. In contrast, according to another embodiment, the gate electrode G may include polycrystalline silicon (poly-Si). The type of material usable as the gate electrode G is not limited. According to one embodiment, the gate electrode G may be used as Vin of the complementary transistor according to the embodiment.

The first source electrode S1 may be disposed on the substrate 10 so as to come into contact with all opposite ends of the first channel layers C1. According to one embodiment, the first source electrode S1 may also extend in the normal direction of the upper surface of the substrate 10, and may have an extending length shorter than the gate electrode G. According to one embodiment, the first source electrode S1 may be used as VDD of the complementary transistor according to the embodiment.

The drain electrode D may be disposed on the substrate 10, in which a lower region of the drain electrode D may come into contact with all one ends of the first channel layers C1, and an upper region of the drain electrode D may surround the second channel layer C2 and the second gate insulating layer GI2 described later.

In other words, the first source electrode S1 may be disposed to come into contact only with the first channel layer C1 between the first channel layer C1 and the second channel layer C2 described later, however, the drain electrode D may be disposed to come into contact with both of the first channel layer C1 and the second channel layer C2 described below. In addition, one region of the drain electrode D surrounding the second channel layer C2 and the second gate insulating layer GI2 described later may overlap with the first source electrode S1 in the extending direction of the gate electrode.

According to one embodiment, the drain electrode D may be disposed to be spaced apart from the first source electrode S1 with the gate electrode G interposed therebetween. According to one embodiment, the drain electrode D may also extend in the normal direction of the upper surface of the substrate 10 and may have an extending length shorter than the gate electrode G and longer than the first source electrode S1. According to one embodiment, the drain electrode D may be used as Vout of the complementary transistor according to the embodiment.

The second gate insulating layer GI2 may be disposed to surround an upper surface and one region of a side surface of the gate electrode G. In other words, the second gate insulating layer GI2 may be disposed to conformally cover the upper region of the gate electrode G along a surface profile thereof. The second gate insulating layer GI2 is configured for electrical insulation between the gate electrode G and the second channel layer C2 described below, and according to one embodiment, may include silicon oxide (SiO₂). In contrast, according to another embodiment, the second gate insulating layer GI2 may include any one of hafnium oxide (HfO₂), aluminum oxide (Al₂O₃), and zirconium oxide (ZrO₂).

The second channel layer C2 may be disposed on the second gate insulating layer GI2. More particularly, the second channel layer C2 may be disposed along a surface profile of the second gate insulating layer GI2. Accordingly, the second channel layer C2 may also surround the upper surface and the predetermined region of the side surface of the gate electrode G. According to one embodiment, the second channel layer C2 may have a second type. For example, the second channel layer C2 may have an N type. According to one embodiment, the second channel layer C2 may include any one of an oxide semiconductor and a two-dimensional material that have N-type characteristics. As described above when the second channel layer C2 is composed of any one of the oxide semiconductor or the two-dimensional material, the channel formation may be achieved through the atomic layer deposition (ALD) process, so that the integration into the three-dimensional structure can be easily implemented. In addition, the channel formation may be achieved through a low-temperature process, so that deterioration of the lower stack due to high temperature heat treatment can be prevented.

The second source electrode S2 may be disposed on the second channel layer C2 to come into contact only with the second channel layer C2 between the first channel layer C1 and the second channel layer C2. In addition, as shown in FIG. 20, the second source electrode S2 may be disposed in the extending direction of the gate electrode G without overlapping with the drain electrode D. Accordingly, parasitic capacitance may be reduced, so that the electrical characteristics of the complementary transistor may be improved. In contrast, when the second source electrode S2 and the drain electrode D are disposed to overlap with each other, a problem may arise in which the electrical characteristics of the complementary transistor deteriorate due to an increase in parasitic capacitance. According to one embodiment, the second source electrode S2 may be used as Ground of the complementary transistor according to the embodiment.

The first interlayer insulating layer ILD1 may be disposed between the substrate 10 and the drain electrode D surrounding the upper region of the gate electrode G to electrically insulate the gate electrode G, the first source electrode S1, and the drain electrode D from each other. In contrast, the second interlayer insulating layer ILD2 may be disposed between the second source electrode S2 and the drain electrode D surrounding the upper region of the gate electrode G to electrically insulate the gate electrode G, the second source electrode S2, and the drain electrode D from each other.

The gate electrode G, the first channel layers C1, the first source electrode S1, and the drain electrode D may be defined as a first transistor TR1. In contrast, the gate electrode G, the second channel layer C2, the second source electrode S2, and the drain electrode D may be defined as a second transistor TR2.

The first transistor TR1 may have a gate-all-around (GAA) structure in which a plurality of the first channel layers C1 are surrounded by the gate electrode G. In contrast, the second transistor TR2 may have a channel-all-around (CAA) structure in which the second channel layer C2 surrounds the gate electrode G. In addition, the second transistor TR2 may have a structure stacked on top of the first transistor TR1 along the normal direction of the upper surface of the substrate 10.

As a result, the three-dimensional monolithic complementary transistor according to the second embodiment may have a structure in which an N-type transistor having a CAA structure is stacked on top of a P-type transistor having a GAA structure, and share the gate electrode G and the drain electrode D.

The three-dimensional monolithic complementary transistor according to the second embodiment of the present invention has been described. Hereinafter, a method for manufacturing the three-dimensional monolithic complementary transistor according to the second embodiment of the present invention will be described.

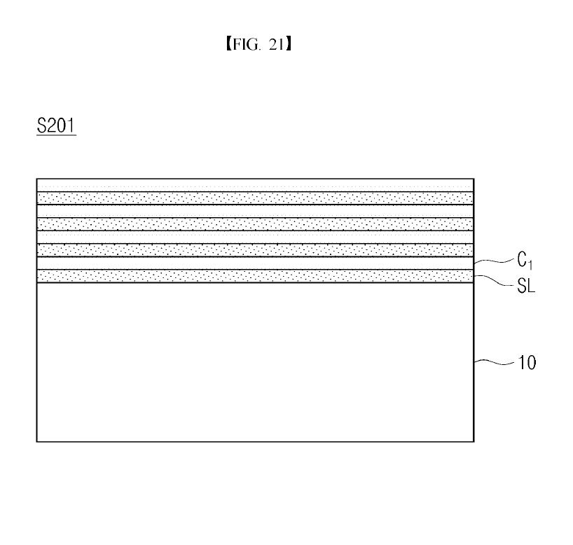

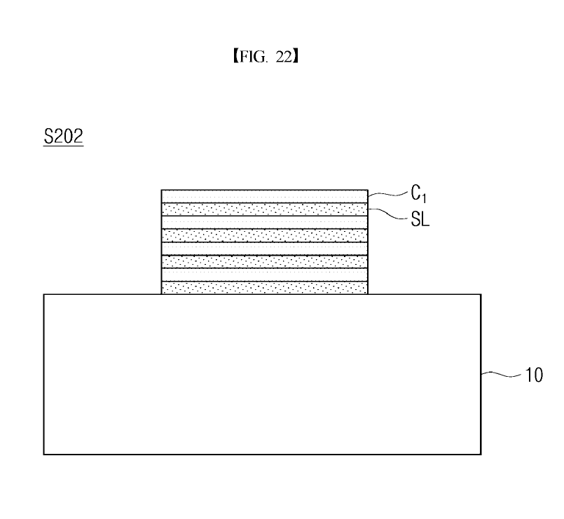

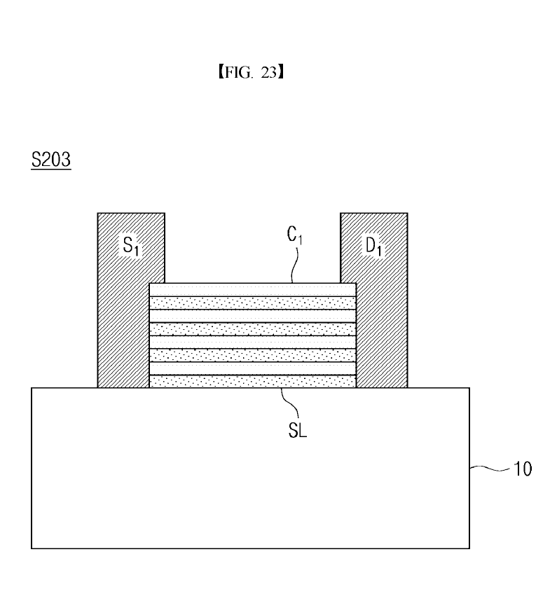

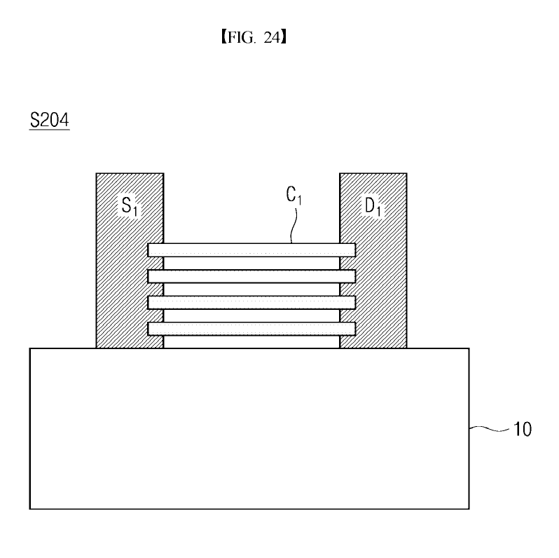

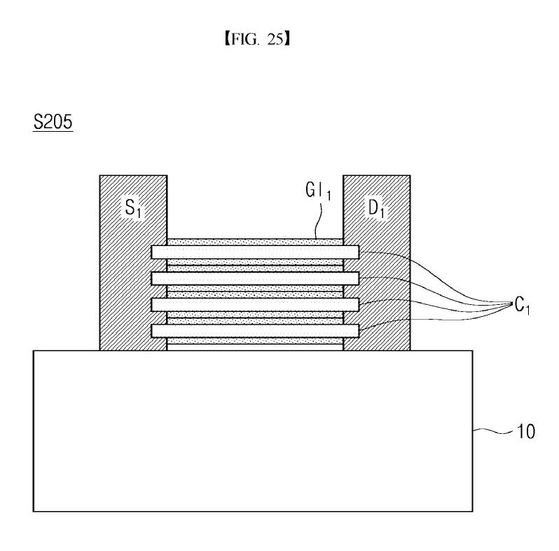

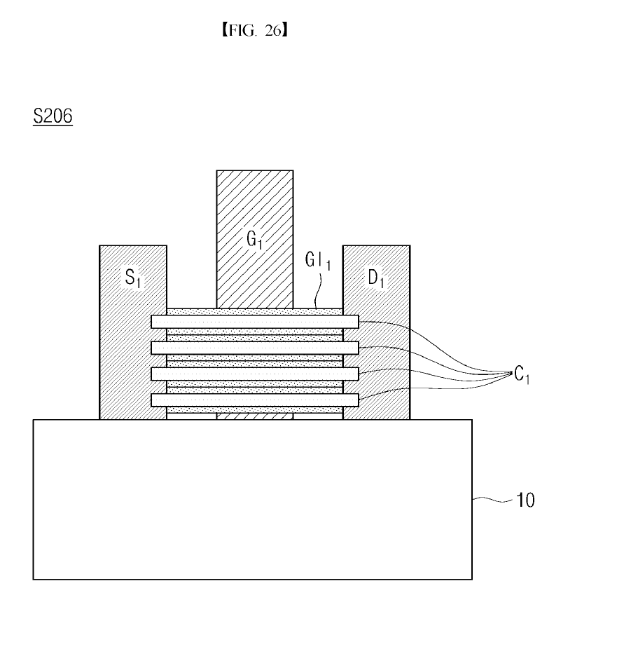

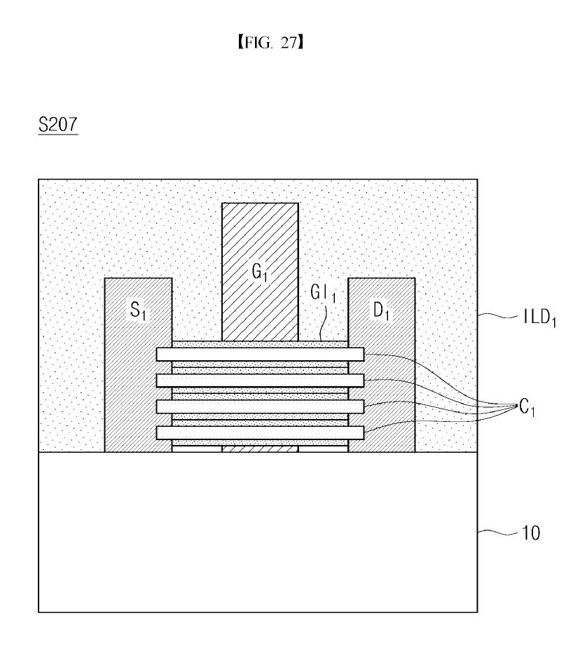

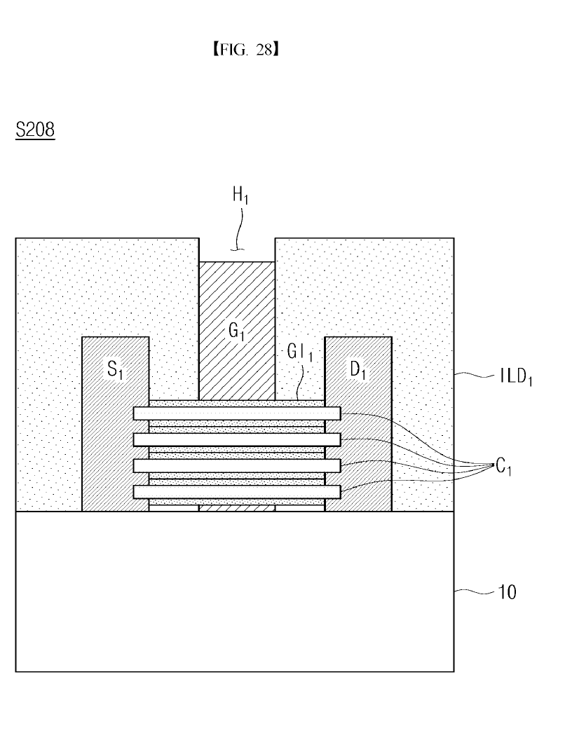

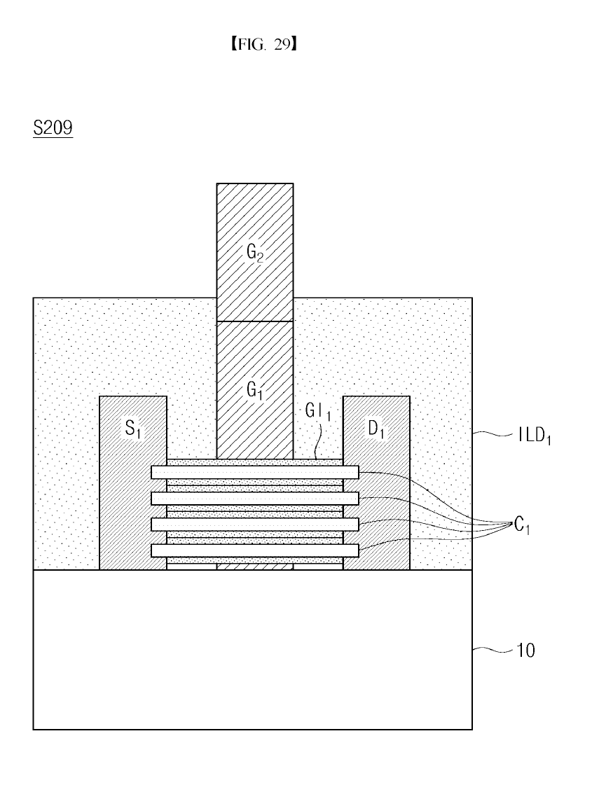

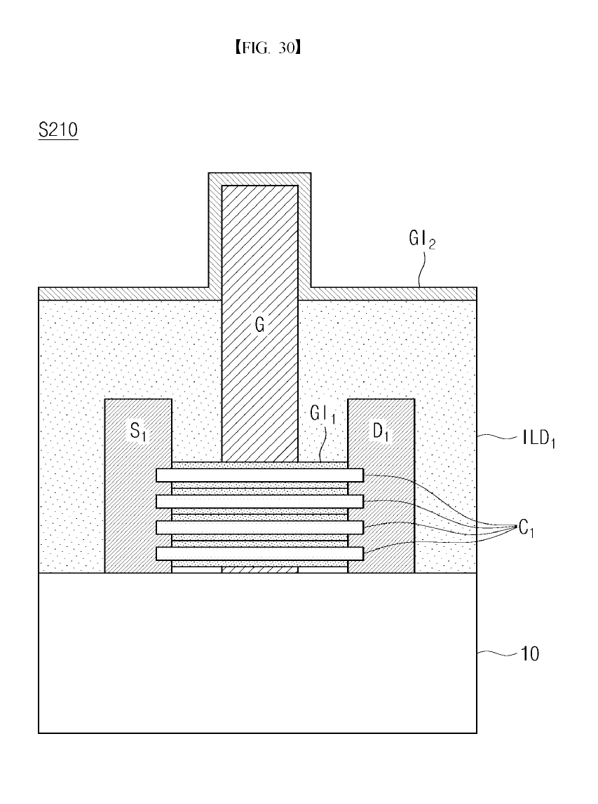

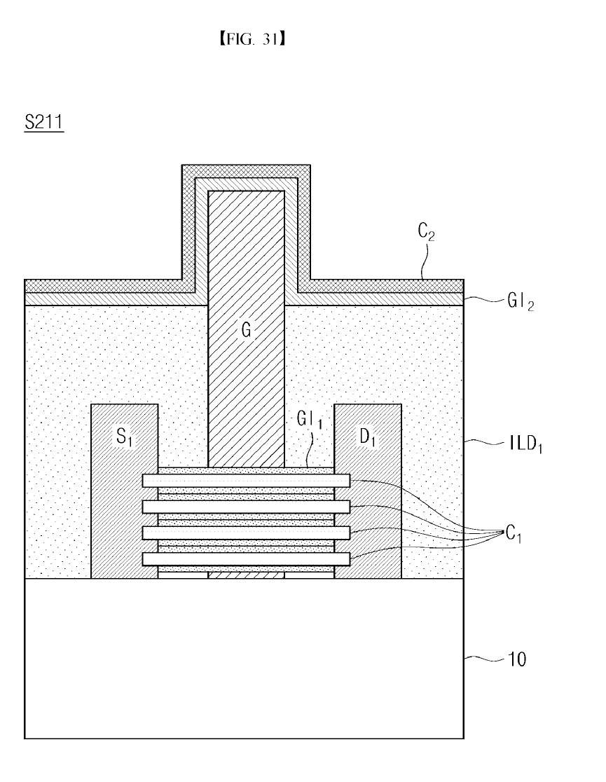

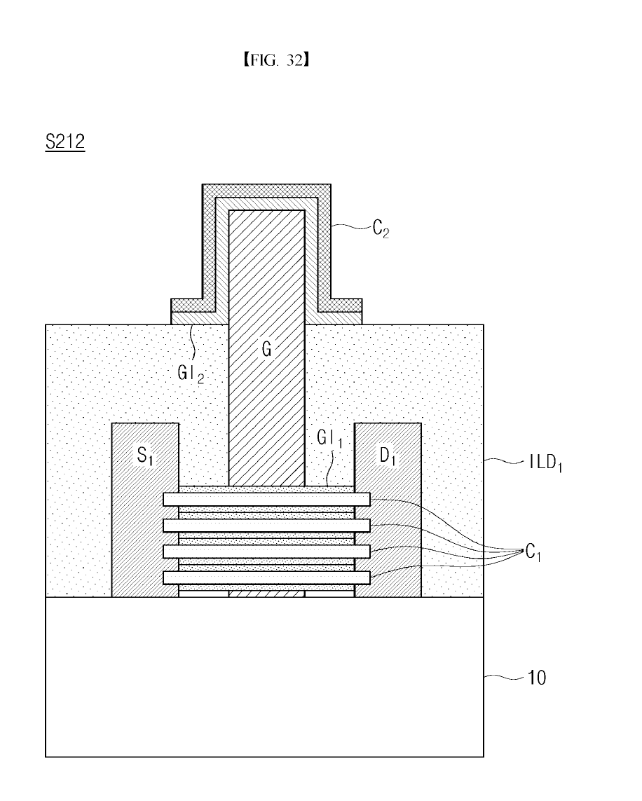

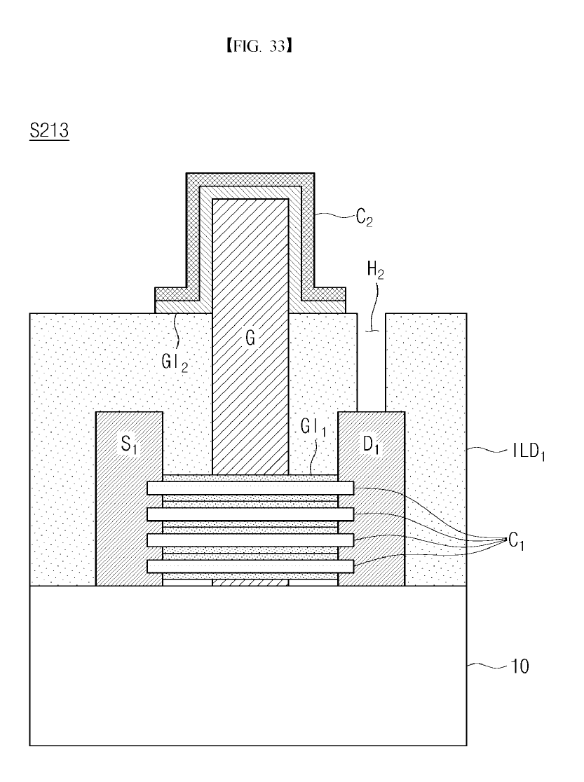

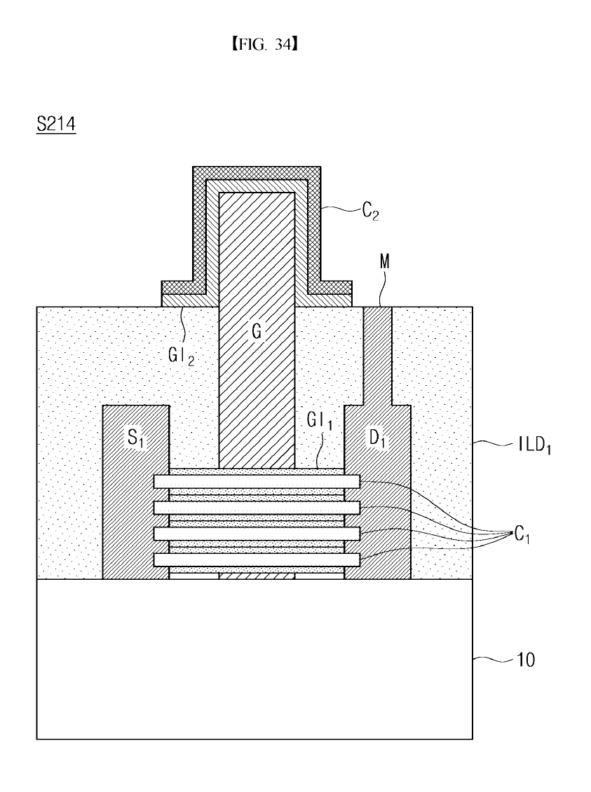

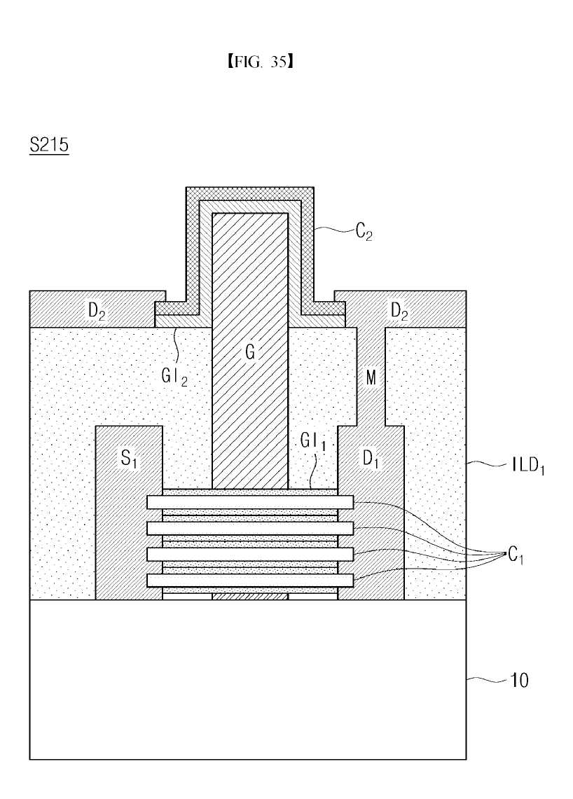

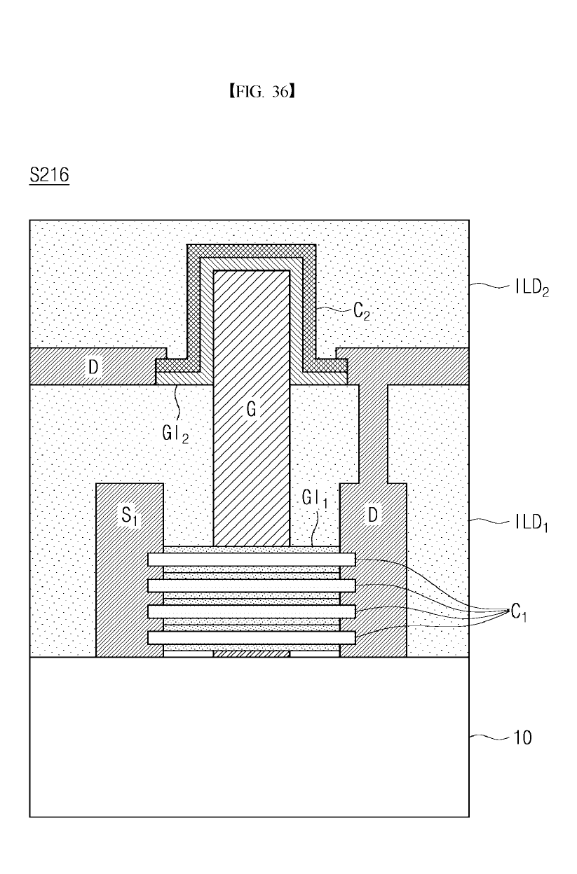

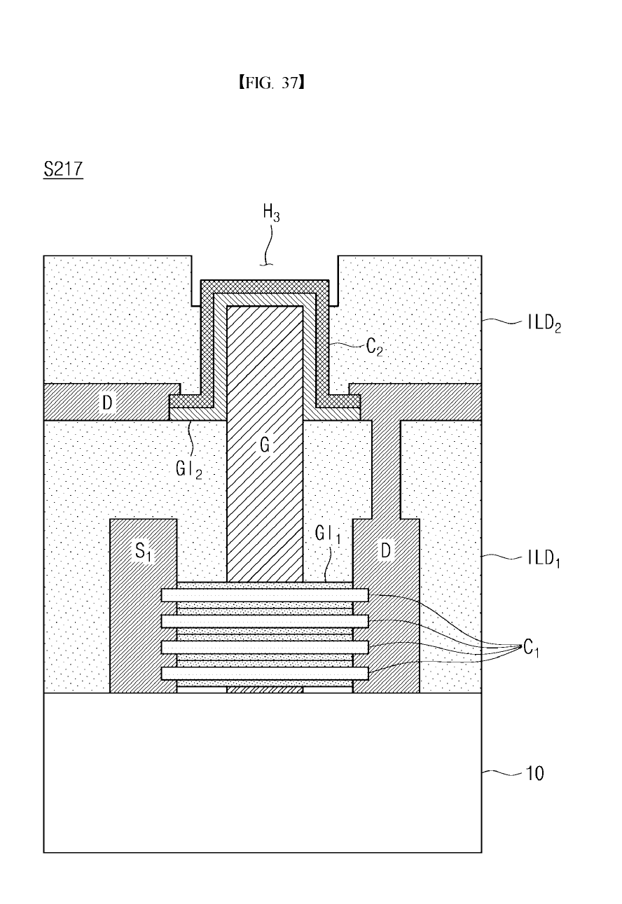

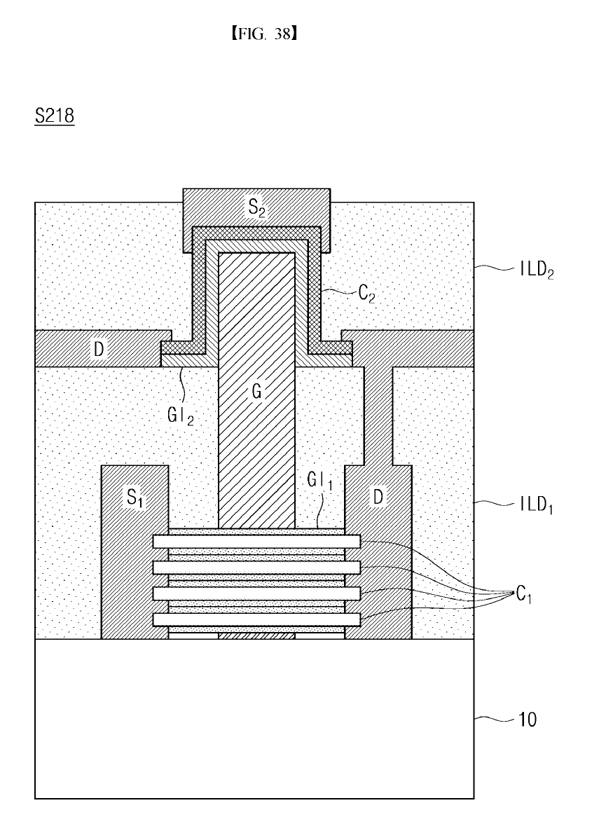

FIG. 21 is a view for explaining step S201 of the method for manufacturing the three-dimensional monolithic complementary transistor according to the second embodiment of the present invention; FIG. 22 is a view for explaining step S202 of the method for manufacturing the three-dimensional monolithic complementary transistor according to the second embodiment of the present invention; FIG. 23 is a view for explaining step S203 of the method for manufacturing the three-dimensional monolithic complementary transistor according to the second embodiment of the present invention; FIG. 24 is a view for explaining step S204 of the method for manufacturing the three-dimensional monolithic complementary transistor according to the second embodiment of the present invention; FIG. 25 is a view for explaining step S205 of the method for manufacturing the three-dimensional monolithic complementary transistor according to the second embodiment of the present invention; FIG. 26 is a view for explaining step S206 of the method for manufacturing the three-dimensional monolithic complementary transistor according to the second embodiment of the present invention; FIG. 27 is a view for explaining step S207 of the method for manufacturing the three-dimensional monolithic complementary transistor according to the second embodiment of the present invention; FIG. 28 is a view for explaining step S208 of the method for manufacturing the three-dimensional monolithic complementary transistor according to the second embodiment of the present invention; FIG. 29 is a view for explaining step S209 of the method for manufacturing the three-dimensional monolithic complementary transistor according to the second embodiment of the present invention; FIG. 30 is a view for explaining step S210 of the method for manufacturing the three-dimensional monolithic complementary transistor according to the second embodiment of the present invention; FIG. 31 is a view for explaining step S211 of the method for manufacturing the three-dimensional monolithic complementary transistor according to the second embodiment of the present invention; FIG. 32 is a view for explaining step S212 of the method for manufacturing the three-dimensional monolithic complementary transistor according to the second embodiment of the present invention; FIG. 33 is a view for explaining step S213 of the method for manufacturing the three-dimensional monolithic complementary transistor according to the second embodiment of the present invention; FIG. 34 is a view for explaining step S214 of the method for manufacturing the three-dimensional monolithic complementary transistor according to the second embodiment of the present invention; FIG. 35 is a view for explaining step S215 of the method for manufacturing the three-dimensional monolithic complementary transistor according to the second embodiment of the present invention; FIG. 36 is a view for explaining step S216 of the method for manufacturing the three-dimensional monolithic complementary transistor according to the second embodiment of the present invention; FIG. 37 is a view for explaining step S217 of the method for manufacturing the three-dimensional monolithic complementary transistor according to the second embodiment of the present invention; and FIG. 38 is a view for explaining step S218 of the method for manufacturing the three-dimensional monolithic complementary transistor according to the second embodiment of the present invention.

Referring to FIG. 21, a stack structure may be formed in which a sacrificial layer SL and a first channel layer C1 are alternately and repeatedly stacked on a substrate 10 (S201). According to one embodiment, the sacrificial layer SL may include silicon or germanium, and the first channel layer C1 may include P-type silicon.

Referring to FIGS. 22 and 23, the stack structure may be etched to expose one region of the substrate 10 (S202), and a first source electrode S1 and a first drain electrode D1 may be formed to come into contact one side and an opposite side of the etched stack structure, respectively (S203).

Referring to FIGS. 24 to 26, the sacrificial layers SL may be removed to form empty spaces between the adjacent first channel layers C1 (S204), a plurality of first gate insulating layers GI1 may be formed to surround the first channel layers C1 within the formed empty spaces (S205), and thereafter, a first gate electrode G1 may be formed on the substrate 10 to extend in the normal direction of the upper surface of the substrate 10 (S206). According to one embodiment, the first channel layer C1 and the first gate insulating layers GI1 may be formed to surround the first gate electrode G1.

Referring to FIGS. 27 to 29, a first interlayer insulating layer ILD1 may be formed on the substrate 10 to cover the first channel layers C1, the first source electrode S1, the first drain electrode D1, the first gate insulating layer GI1, and the first gate electrode G1 (S207), a first hole H1 may be formed by etching one region of the first interlayer insulating layer ILD1 to expose one region of the first gate electrode G1 (S208), and a second gate electrode G2 may be formed on the exposed first gate electrode G1, that is, in the first hole H1 to extend along the extending direction of the first gate electrode G1 (S209). In addition, the second gate electrode G2 may be formed to be exposed to an outside of the first interlayer insulating layer ILD1. According to one embodiment, the first gate electrode G1 and the second gate electrode G2 may include the same material, and the first gate electrode G1 and the second gate electrode G2 may form the gate electrode G described with reference to FIG. 20.

Referring to FIGS. 30 to 32, a second gate insulating layer GI2 may be formed to conformally cover the upper surface of the first interlayer insulating layer ILD1 and the exposed gate electrode G (S210), a second channel layer C2 may be formed on the second gate insulating layer GI2 along a surface profile of the second gate insulating layer GI2 (S211), and the second channel layer C2 and the second gate insulating layer GI2 may be etched to expose one region of the upper surface of the first interlayer insulating layer ILD1 (S212).

Referring to FIGS. 33 to 35, a second hole H2 may be formed by etching one region of the first interlayer insulating layer ILD1 to expose one region of the first drain electrode D1 (S213), the second hole H2 may be filled with a metal M (S214), and a second drain electrode D2 may be formed on the first interlayer insulating layer ILD1 to surround the second gate insulating layer GI2 and the second channel layer C2 (S215). The first drain electrode D1, the metal filled in the second hole H2, and the second drain electrode D2 may include the same material, and the first drain electrode D1, the metal filled in the second hole H2, and the second drain electrode D2 may form the drain electrode D described with reference to FIG. 20.

Referring to FIGS. 36 to 38, a second interlayer insulating layer ILD2 may be formed on the first interlayer insulating layer ILD1 to cover the drain electrode D and the second channel layer C2 (S216), a third hole H3 may be formed by etching one region of the second interlayer insulating layer ILD2 to expose the second channel layer C2 (S217), and a second source electrode S2 may be formed on the exposed second channel layer C2, that is, in the third hole H3 (S218), in which the second source electrode S2 may be formed in the extending direction of the gate electrode G without overlapping with the drain electrode D. Accordingly, the three-dimensional monolithic complementary transistor according to the second embodiment may be manufactured.

Although the present invention has been described in detail with reference to the preferred embodiments, the present invention is not limited to the specific embodiments and will be interpreted by the following claims. In addition, it will be apparent that a person having ordinary skill in the art may carry out various deformations and modifications for the embodiments described as above within the scope without departing from the present invention.

### 【Industrial Applicability】

The present invention may be used in the semiconductor industry.

What is claimed is:

1. A three-dimensional monolithic complementary transistor comprising:a gate electrode extending in a first direction to an upper surface of a substrate;a first channel layer disposed below the gate electrode;a second channel layer surrounding an upper surface and one region of side surfaces of the gate electrode;a drain electrode disposed on the substrate to come into contact with the first channel layer and the second channel layer;a first source electrode disposed on the substrate to come into contact only with the first channel layer between the first channel layer and the second channel layer; anda second source electrode disposed on the second channel layer to come into contact only with the second channel layer between the first channel layer and the second channel layer.

2. The three-dimensional monolithic complementary transistor of claim 1 wherein the second source electrode and the drain electrode are disposed without overlapping with each other in the first direction of the gate electrode.

3. The three-dimensional monolithic complementary transistor of claim 1 wherein the first source electrode and the drain electrode overlap with each other in the first direction of the gate electrode.

4. The three-dimensional monolithic complementary transistor of claim 1 wherein the first channel layer includes a P type, and the second channel layer includes an N type.

5. The three-dimensional monolithic complementary transistor of claim 1 wherein the first channel layer includes silicon (Si).

6. The three-dimensional monolithic complementary transistor of claim 1 wherein the second channel layer includes any one of an oxide semiconductor and a two-dimensional material.

7. The three-dimensional monolithic complementary transistor of claim 1 wherein the gate electrode, the first channel layer, the drain electrode, and the first source electrode are defined as a first transistor, and the gate electrode, the second channel layer, the drain electrode, and the second source electrode are defined as a second transistor.

8. A three-dimensional monolithic complementary transistor comprising:a gate electrode extending in a first direction to an upper surface of a substrate;a plurality of first channel layers spaced apart from each other along the first direction of the gate electrode, and disposed on the substrate so as to be adjacent to a lower region of the gate electrode;a second channel layer surrounding an upper surface and one region of side surfaces of the gate electrode;a drain electrode disposed on the substrate to come into contact with the first channel layers and the second channel layer;a first source electrode disposed on the substrate to come into contact only with the first channel layers between the first channel layers and the second channel layer; anda second source electrode disposed on the second channel layer to come into contact only with the second channel layer between the first channel layers and the second channel layer.

9. The three-dimensional monolithic complementary transistor of claim 8, wherein the gate electrode is surrounded by the first channel layers.

10. The three-dimensional monolithic complementary transistor of claim 8, wherein the drain electrode comes into contact with one end of each of the first channel layers.

11. The three-dimensional monolithic complementary transistor of claim 8, wherein the first source electrode comes into contact with an opposite end of each of the first channel layers.

12. The three-dimensional monolithic complementary transistor of claim 8, wherein the second source electrode and the drain electrode are disposed without overlapping with each other in the first direction of the gate electrode.

13. The three-dimensional monolithic complementary transistor of claim 8, wherein the first channel layers include a P type, and the second channel layer includes an N type.

14. The three-dimensional monolithic complementary transistor of claim 8, wherein the first channel layers include silicon (Si), and the second channel layer includes any one of an oxide semiconductor and a two-dimensional material.
